(19) United States
(12) Patent Application Publication
(10) Pub. No.: US 2026/0047223 A1
(43) Pub. Date: Feb. 12, 2026

(54) IMAGE SENSING STRUCTURE AND MANUFACTURING METHOD THEREOF

(71) Applicant: TAIWAN SEMICONDUCTOR MANUFACTURING COMPANY LTD., HSINCHU (TW)

(72) Inventors: FENG-CHIEN HSIEH, PINGTUNG COUNTY (TW); KENG-YING LIAO, TAINAN CITY (TW); WEI-LI HU, TAINAN CITY (TW); CHIEN NAN TU, KAOHSIUNG CITY (TW); KUO-CHENG LEE, TAINAN CITY (TW); HSUN-YING HUANG, TAINAN CITY (TW)

(21) Appl. No.: 18/795,224

(22) Filed: Aug. 6, 2024

(51) Int. Cl. H01L 27/146

(52) U.S. Cl. CPC H10F 39/807; H10F 39/011; H10F 39/182

(57) ABSTRACT

The present disclosure provides a method of forming an image sensing structure. The method includes: providing a substrate having a first surface and a second surface opposite to the first surface; forming a first photodiode region and a second photodiode region in the substrate; forming a first transistor and a second transistor on the first surface, wherein the first transistor is over the first photodiode region and the second transistor is over the second photodiode region; and etching the substrate from the second surface to form a first trench recessed from the second surface toward the first surface, wherein the first trench is substantially aligned with the first photodiode region; etching the substrate from the first trench to form a second trench recessed from the first trench toward the second transistor; and depositing silicon into the first trench and the second trench.

### BACKGROUND

CMOS image sensors are used in many types of electronic devices, such as video cameras and digital cameras to, capture images.

As technological standards advance, there is an ever-increasing consumer demand for image-sensing devices that occupy less space, consume less power, and produce greater-quality images at greater speeds. As a result, there remains a need to develop a CMOS image sensor with an improved structure.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flow diagram showing a method for forming an image sensing structure, in accordance with some embodiments of the present disclosure.

FIGS. 2 to 24 are schematic cross-sectional, top or perspective views illustrating sequential operations of the method in FIG. 1 to form an image sensing structure, in accordance with some embodiments of the present disclosure.

FIGS. 25 to 28 show schematic cross-sectional views of other image sensing structures, in accordance with various embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

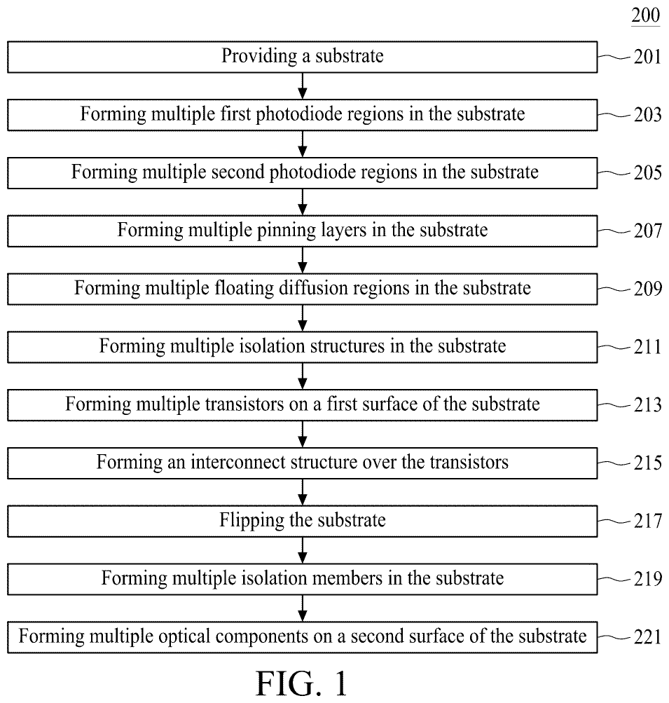

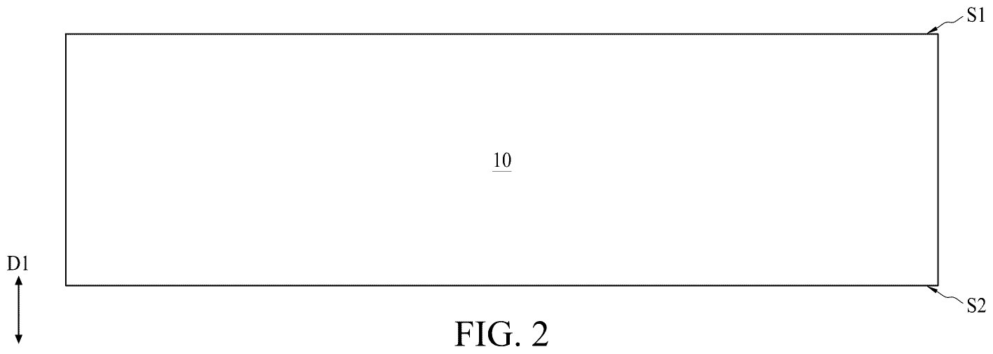

FIG. 1 is a flow diagram showing a method 200 for forming an image sensing structure 210. FIGS. 2 to 23 are schematic cross-sectional, top or perspective views illustrating sequential operations of the method 200 in FIG. 1 to form the image sensing structure 210.

In operation 201 of FIG. 1, a substrate 10 is provided, as shown in FIG. 2. The substrate 10 has a first surface S1 (or a front side S1) and a second surface S2 (or a back side S2) opposite to the first surface S1. The substrate 10 has a thickness along a first direction D1. The substrate 10 includes at least one of silicon (Si), germanium (Ge), gallium (Ga), arsenic (As), phosphorus (P), indium (In), antimonide, SiGe, SiC, GaAs, GaN, GaP, InGaP, InP, InAs, InSb, GaAsP, AlInAs, AlGaAs, GaInAs, GaInP, GaInAsP, or other suitable materials. The substrate 10 includes any type of semiconductor body such as a silicon-on-insulator (SOI) substrate, or the like. Although not shown, the substrate 10 includes one or more semiconductor layers and/or epitaxial layers formed thereon. In some embodiments, the substrate 10 is implanted with dopants of a first conductivity type. In some embodiments, the first conductivity type is P type, and thus the substrate 10 is a P-type substrate. The substrate 10 is configured to sense radiation such as an incident light.

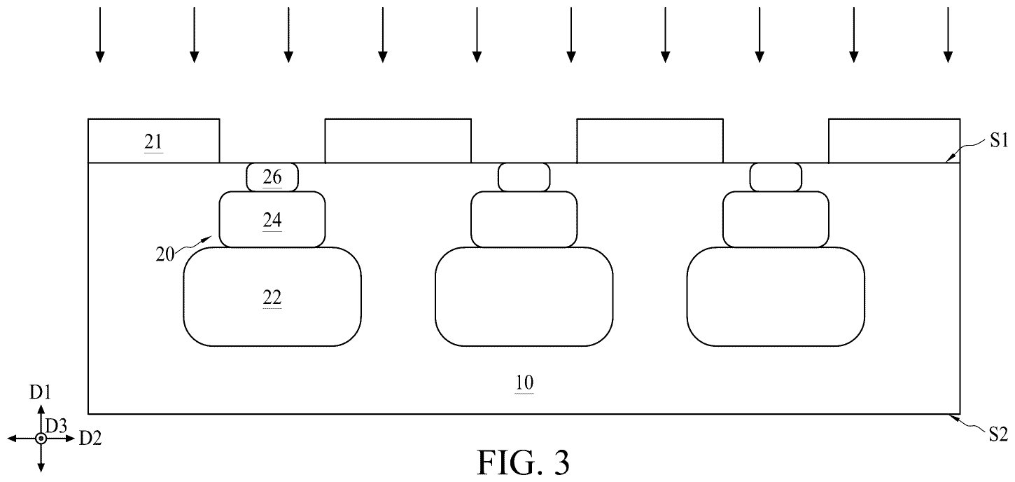

In operation 203 of FIG. 1, multiple first photodiode (PD) regions 20 are formed in the substrate 10, as shown in FIG. 3. To form the first photodiode regions 20, an implant mask 21 is deposited on the first surface S1 of the substrate 10. An implantation operation is performed to implant dopants of a second conductivity type into the substrate 10. In some embodiments, the second conductivity type is N type. The dopants are implanted into the substrate 10 through openings of the implant mask 21. The implantation operation may be performed once or several times to form multiple N-type wells at different depth ranges within the substrate 10. For example, a first well 22 is initially formed in the substrate 10 at a predetermined depth starting from the first surface S1 of the substrate 10. A second well 24 is subsequently formed over the first well 22. A third well 26 is subsequently formed over the second well 24. The order in which the first well 22, the second well 24 and the third well 26 are formed is not limited. In some embodiments, a distribution of the N-type dopants in the substrate 10 are controlled by adjusting a voltage, a dosage or an implantation time used to direct the N-type dopants into the substrate 10. In some embodiments, volumes of the first well 22, the second well 24 and the third well 26 are adjustable. The first well 22, the second well 24 and the third well 26 may have different sizes. The size of the first well 22 may be greater than the size of the second well 24, and the size of the second well 24 may be greater than the size of the third well 26. In some embodiments, the first well 22, the second well 24 and the third well 26 have different concentrations of dopants. The first well 22 may contact the second well 24, and the second well 24 may contact the third well 26. The implant mask 21 is removed after the first to third wells 22, 24 and 26 are formed.

In some embodiments, the substrate 10 (which is P-type) and the first to third wells 22, 24 and 26 (which are N-type) include opposite types of dopants, and thus a P-N junction is formed between the substrate 10 and the first to third wells 22, 24 and 26. In some embodiments, portions of the substrate 10, the first well 22, the second well 24 and the third well 26 including the P-N junction form the first photodiode regions 20. In some embodiments, the first photodiode regions 20 are arranged along a second direction D2 perpendicular to the first direction D1. In some embodiments, the first photodiode region 20 extends along a third direction D3 (i.e., into the sheet of FIG. 3) perpendicular to the first direction D1 and the second direction D2.

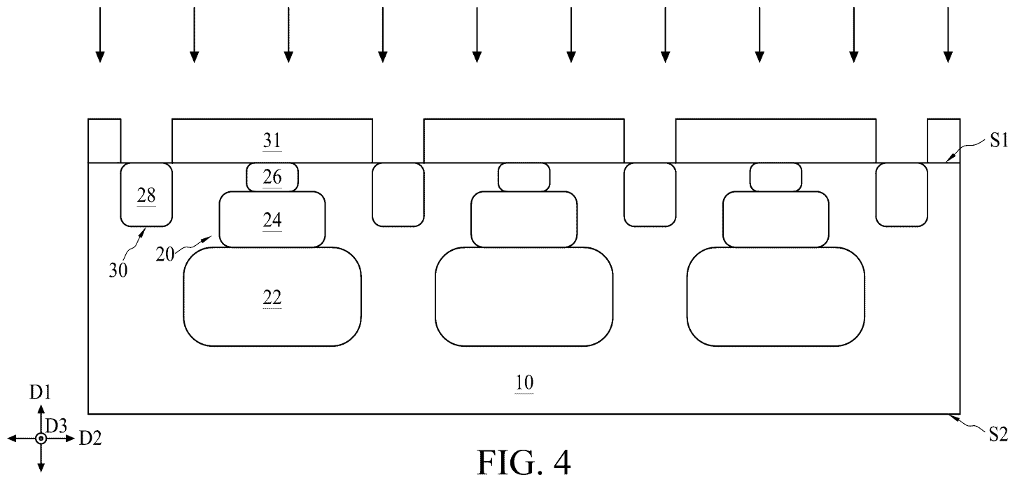

In operation 205 of FIG. 1, multiple second photodiode regions 30 are formed in the substrate 10, as shown in FIG. 4. To form the second photodiode regions 30, an implant mask 31 is deposited on the first surface S1 of the substrate 10. An implantation operation is performed to implant dopants of the second conductivity type into the substrate 10. The dopants are implanted into the substrate 10 through openings of the implant mask 31. Multiple fourth wells 28 are formed in the substrate 10 and near the first surface S1. The implant mask 31 is removed after the fourth wells 28 are formed. In some embodiments, the first photodiode region 20 and the second photodiode region 30 have different volumes. In some embodiments, the first photodiode region 20 has a size greater than a size of the second photodiode region 30.

In some embodiments, the substrate 10 (which is P-type) and the fourth well 28 (which is N-type) include opposite types of dopants, and thus a P-N junction is formed between the substrate 10 and the fourth well 28. In some embodiments, portions of the substrate 10 and the fourth well 28 including the P-N junction form the second photodiode regions 30. In some embodiments, the first photodiode regions 20 and the second photodiode regions 30 are alternately arranged along the second direction D2. In some embodiments, the second photodiode regions 30 extend along the third direction D3 (i.e., into the sheet of FIG. 4).

In some embodiments, the first photodiode region 20 and the second photodiode region 30 are used to collect photoelectrons. The first photodiode region 20 and the second photodiode region 30 have different charge-storing capacities. In some embodiments, the first photodiode region 20 has a charge-storing capacity greater than a charge-storing capacity greater of the second photodiode region 30. In some embodiments, the first photodiode region 20 and second photodiode region 30 are separately used to convert photons into electrical currents.

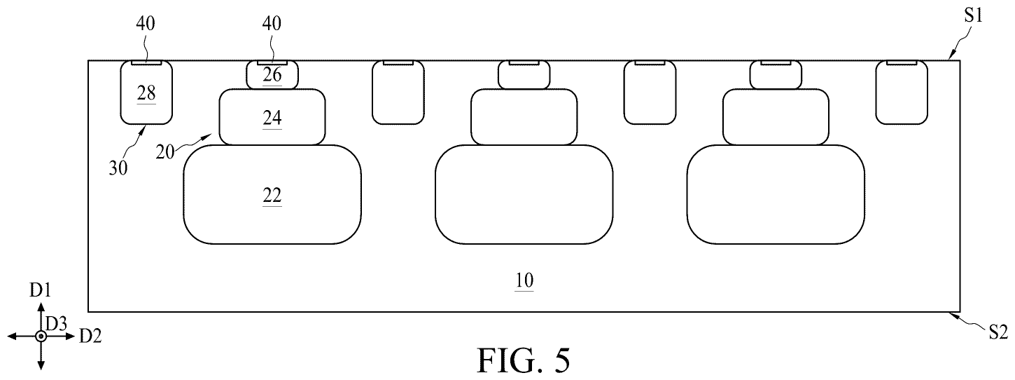

In operation 207 of FIG. 1, multiple pinning layers 40 are formed in the substrate 10, as shown in FIG. 5. To form the pinning layers 40, an implant mask (not shown) is deposited on the first surface S1 of the substrate 10. An implantation operation is performed to implant dopants of the first conductivity type into top portions of the substrate 10, thus forming the pinning layers 40. In some embodiments, the pinning layers 40 are formed on top portions of the first photodiode regions 20 and the second photodiode regions 30. The pinning layers 40 are proximal to the first surface S1. In some embodiments, the pinning layer 40 includes dopants of the first conductivity type with a dopant concentration greater than that of the substrate 10.

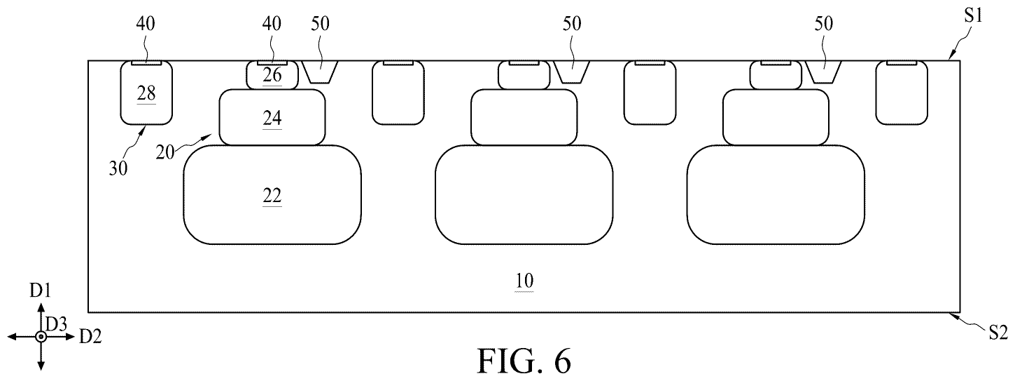

In operation 209 of FIG. 1, multiple floating diffusion regions (or floating nodes) 50 are formed in the substrate 10, as shown in FIG. 6. To form the floating diffusion regions 50, an implant mask (not shown) is deposited on the first surface S1 of the substrate 10. An implantation operation is performed to implant dopants of the second conductivity type into other top portions of the substrate 10, thus forming the floating diffusion regions 50. In some embodiments, the floating diffusion regions 50 are proximal to the first surface S1. In some embodiments, the floating diffusion region 50 includes dopants of the second conductivity type with a greater concentration than those of the first photodiode region 20 or the second photodiode region 30.

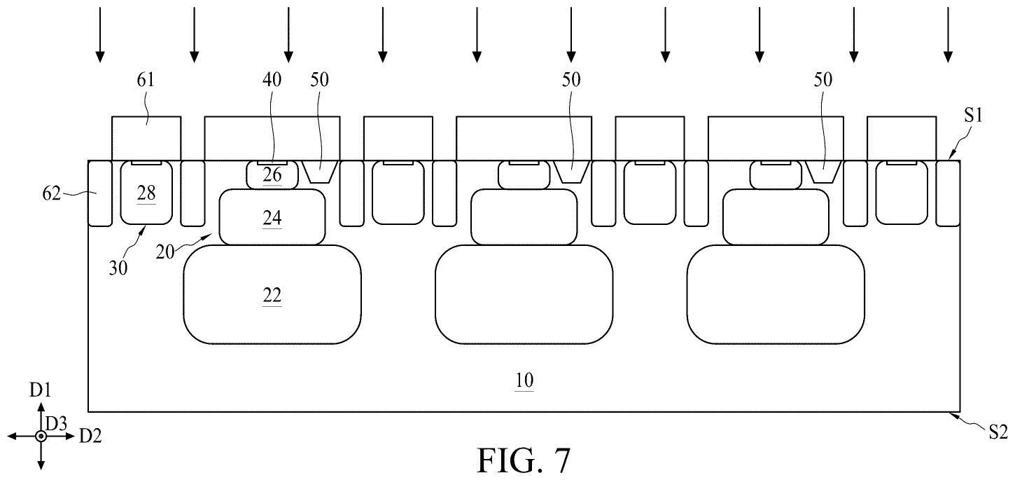

In operation 211 of FIG. 1, multiple isolation structures 60 are formed in the substrate 10, as shown in FIGS. 7 to 10. Referring to FIG. 7, an implant mask 61 is deposited on the first surface S1 of the substrate 10. An implantation operation is performed to implant dopants of the first conductivity type into the substrate 10. The dopants are implanted into the substrate 10 through openings of the implant mask 61, thus forming multiple P-type wells 62 in the substrate 10. The implant mask 61 is removed after the P-type wells 62 are formed. The P-type well 62 has a predetermined depth measured from the first surface S1 of the substrate 10. In some embodiments, the P-type well 62 is between the first photodiode region 20 and the second photodiode region 30. In some embodiments, the P-type well 62 includes dopants of the first conductivity type with a concentration greater than that of the substrate 10.

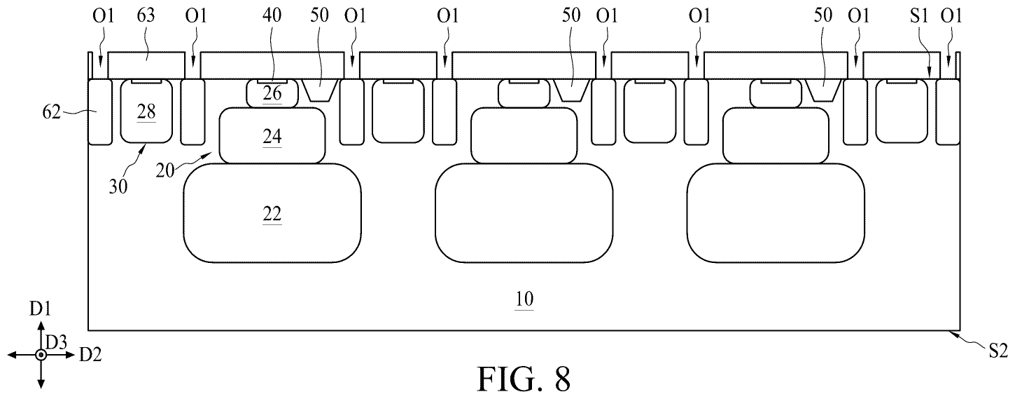

Referring to FIG. 8, a patterned photoresist 63 is formed on the first surface S1 of the substrate 10. The patterned photoresist 63 includes multiple openings O1, each of which exposes portions of the substrate 10. In some embodiments, the opening O1 is over and substantially aligned with the underlying P-type well 62.

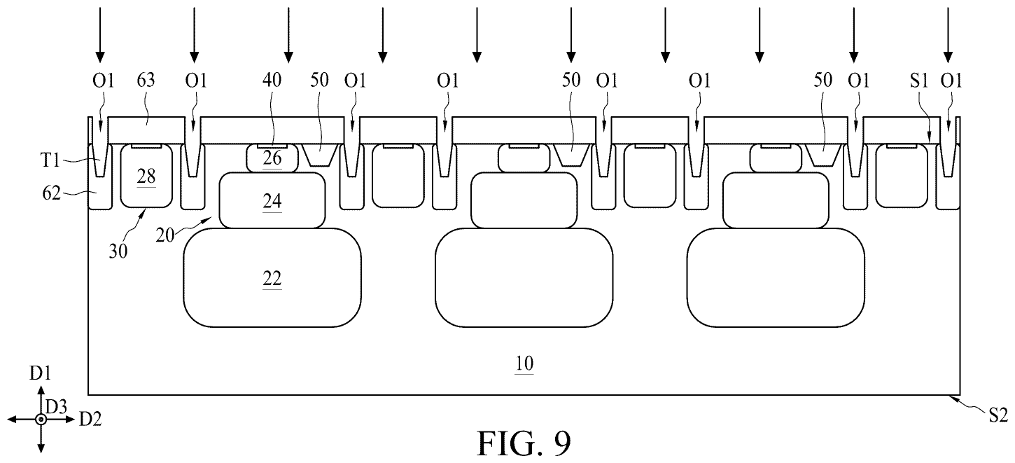

Referring to FIG. 9, an etching operation is performed to remove portions of the substrate 10 to form multiple trenches T1. In some embodiments, the etching operation removes a portion of each of the P-type wells 62 from the first surface S1. The etching operation includes at least one of a dry etching process, a wet etching process, an anisotropic etching process, an isotropic etching process, a plasma etching process or another suitable etching process. The patterned photoresist 63 is removed after the trenches T1 are formed. In some embodiments, the trench T1 extends into the P-type well 62 without penetrating the P-type well 62. That is, the trench T1 is formed within the P-type well 62. The trench T1 may be referred to as a shallow trench.

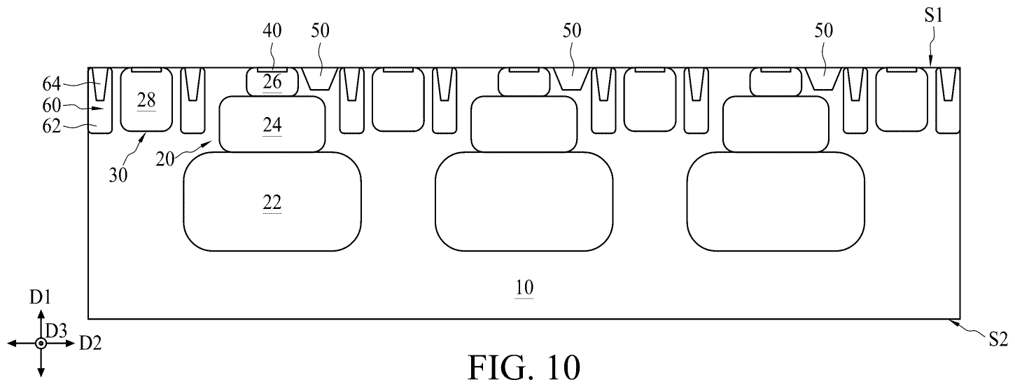

Referring to FIG. 10, a dielectric material is deposited to fill the trenches T1. The dielectric material includes at least one of silicon oxide (SiO), silicon nitride (SiN), aluminum oxide (AlO), tantalum oxide (TaO), hafnium oxide (HfO), hafnium silicon oxide (HfSiO), hafnium aluminum oxide (HfAlO), hafnium tantalum oxide (HfTaO), fluorinated silica glass (FSG), a combination thereof, or other suitable materials. Formation of trench isolations 64 is followed by planarizing a top surface of the dielectric material. The trench isolation 64 has a top surface coplanar with the first surface S1 of the substrate 10. The trench isolation 64 may be referred to as a shallow trench isolation (STI). In some embodiments, the trench isolation 64 is formed within the P-type well 62. The P-type well 62 laterally surrounds the trench isolation 64. The isolation structure 60 includes the trench isolation 64 and the P-type well 62. In some embodiments, a bottom surface of the isolation structure 60 is lower than a bottom surface of the third well 26, a bottom surface of the fourth well 28, a bottom surface of the pinning layer 40 or a bottom surface of the floating diffusion region 50. In some embodiments, the bottom surface of the isolation structure 60 is substantially level or coplanar with the bottom surface of the second photodiode region 30. In some embodiments, the isolation structure 60 is between an adjacent pair of the first photodiode region 20 and the second photodiode region 30. The isolation structure 60 is at least laterally offset from the first photodiode region 20 and the second photodiode region 30. In some embodiments, the isolation structure 60 provides for electrical cross-talk reduction or elimination where an electrical signal is generated from incident radiation that passes between adjacent first photodiode region 20 and second photodiode region 30.

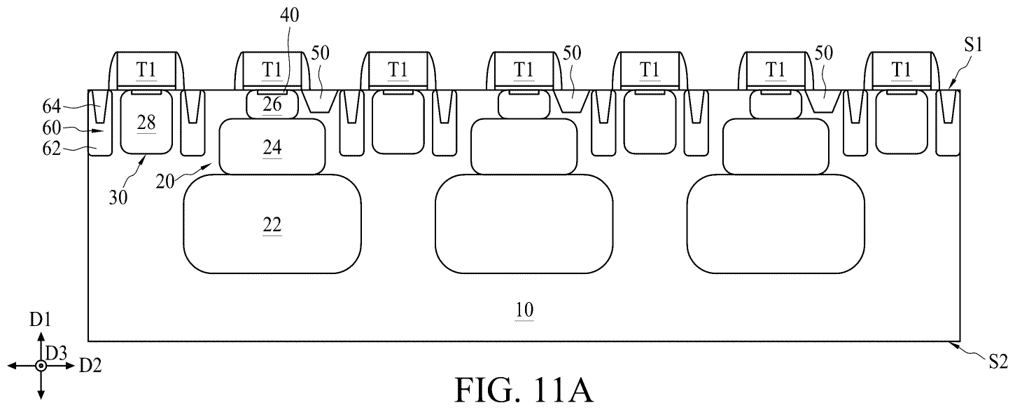

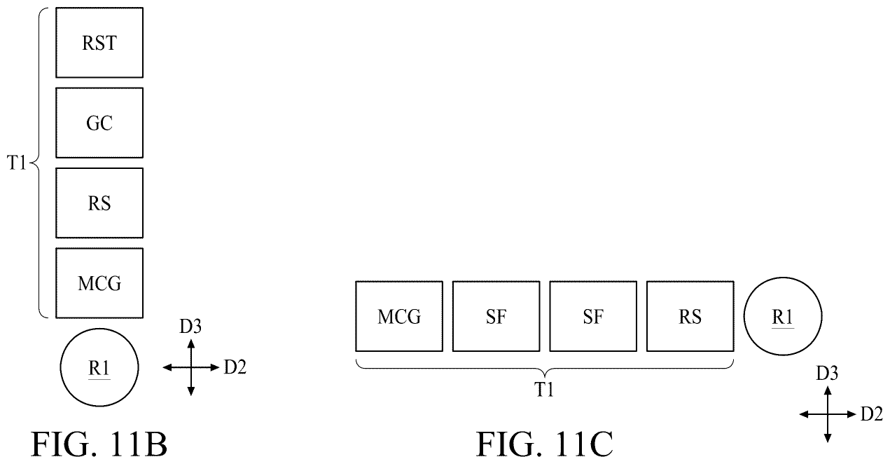

In operation 213 of FIG. 1, multiple transistors T1 are formed on the first surface S1 of the substrate 10, as shown in FIGS. 11A to 11C. Referring to FIG. 11A, the transistors T1 may be formed on the first surface S1 or partially embedded in the substrate 10. Although not specifically illustrated, the transistors T1 are formed using photolithography, etching, epitaxy, implantation, sputtering, deposition, planarization or other suitable methods. The profile of the transistors T1 shown in FIG. 11A and following figures is only illustrative and not limited thereto. In some embodiments, the transistor T1 includes a gate dielectric layer, a gate structure on the gate dielectric layer, a gate spacer surrounding the gate structure and a source/drain structure below the gate spacer. In some other embodiments, the transistor T1 only includes a gate structure. In some embodiments, the transistor T1 is a transfer (TX) transistor, a reset (RST) transistor, a source follower (SF) transistor, a row selection (RS) transistor, a middle conversion gain (MCG) transistor or a graded-channel (GC) transistor. In some embodiments, the transistor T1 includes two or more of the above transistors. It is noted that a single transistor T1 shown in FIG. 11A may represent one or more of the transistors such as the RST transistor, the SF transistor, the RS transistor or the like arranged along the third direction D3 (i.e., into the sheet of FIG. 11A). The transistors are electrically connected to each other in series or in parallel.

FIGS. 11B and 11C show different arrangements of the transistors T1. In some embodiments, the transistors T1 are arranged along the third direction D3, as shown in FIG. 11B. In some embodiments, the transistors T1 are arranged along the second direction D2, as shown in FIG. 11C. The arrangements of the transistors T1 shown in FIGS. 11B and 11C are only illustrative and not limited thereto. In some embodiments, a protection element R1 is electrically connected to one or some of the transistors T1. In some embodiments, the protection element R1 is an N-type/P-type pick-up region (or, simply, an N/P pick-up or N/P tap). In such embodiments, the protection element R1 is used to eliminate charge build-up or avoid latch-up. In some embodiments, the protection element R1 is a protection diode. In such embodiments, the protection diode is used to conduct in an event of excessive voltage being applied to a circuit including the transistors T1. The protection diode may protect the transistors T1 from reverse voltages. In some embodiments, the protection element R1 is an electrostatic-discharge (ESD) diode. In such embodiments, the ESD diode is used to protect electronics from an inevitable release of stored static charges accumulated in the substrate 10. In some embodiments, the floating diffusion region 50 is electrically connected to the transistor T1. The floating diffusion region 50 may function as a drain region of the transistor T1 when the transistor T1 does not include a source/drain structure. In some embodiments, the transistor T1 is used to read out a signal charge corresponding to detect a signal strength of radiation impinging on the first photodiode region 20 or the second photodiode region 30.

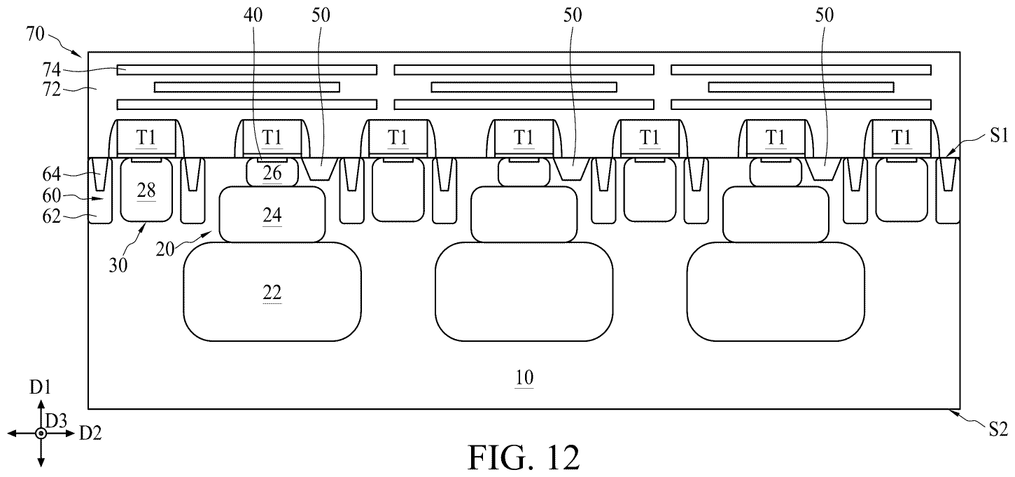

In operation 215 of FIG. 1, an interconnect structure 70 is formed over the transistors T1, as shown in FIG. 12. The interconnect structure 70 includes one or more interlayer dielectric (ILD) layers 72 and multiple conductive structures 74 in the ILD layer(s) 72. Although not specifically illustrated, the transistors T1 are formed using photolithography, etching, epitaxy, implantation, sputtering, deposition, planarization or other suitable methods. The ILD layer 72 may be formed of silicon oxide, silicon nitride, fluorinated silica glass (FSG), a low-k material, a combination thereof, or other suitable materials. The conductive structures 74 may be formed of copper (Cu), cobalt (Co), aluminum (Al), silver (Ag), gold (Au), tungsten (W), a combination thereof, or other suitable materials. The positions and configurations of the conductive structures 74 may vary depending upon design needs. The conductive structures 74 have at least one of contacts, vias, metal lines, or other types of structures. The conductive structures 74 are interconnected by vias or contacts embedded in the ILD layer 72. The transistors T1 are covered and surrounded by the ILD layer 72. The interconnect structure 70 is electrically connected to the transistors T1.

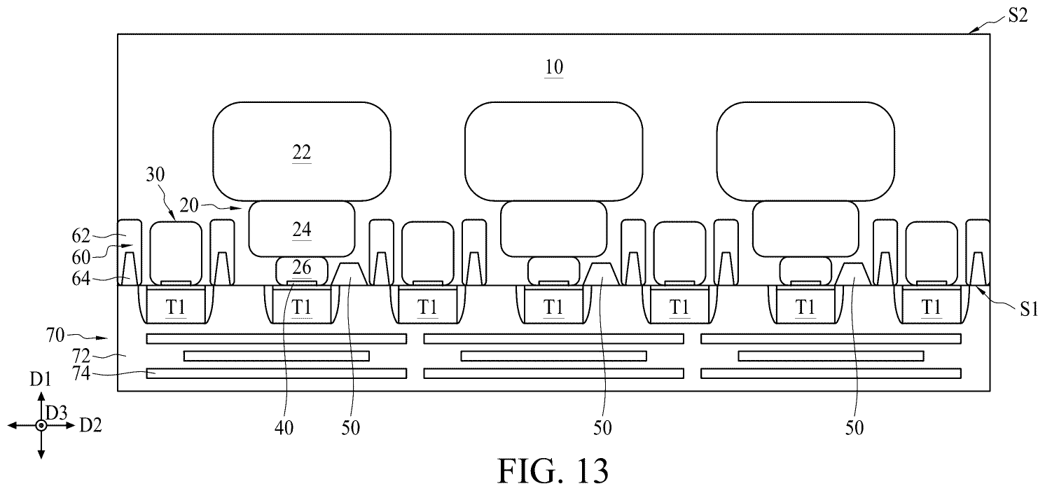

In operation 217 of FIG. 1, the substrate 10 is flipped, as shown in FIG. 13. To flip the substrate 10, a carrier wafer (not shown) is bonded to the substrate 10 through the interconnect structure 70. The substrate 10 is flipped with the second surface S2 facing upwards. The carrier wafer may be bonded to the substrate 10 in subsequent operations of the method 200 and can be removed after the formation of the image sensing structure 210 is complete.

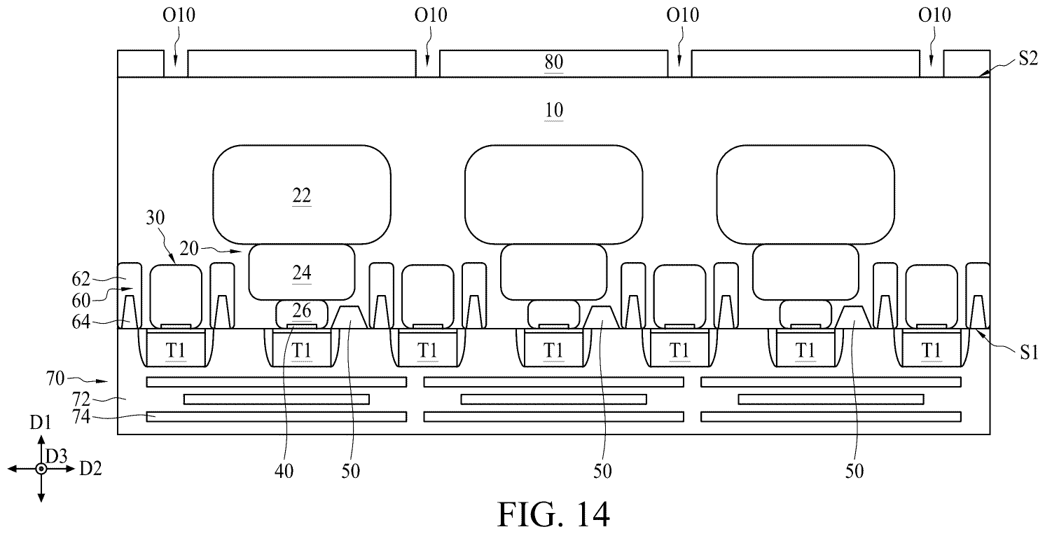

In operation 219 of FIG. 1, multiple isolation members 100 are formed in the substrate 10, as shown in FIGS. 14 to 22. Referring to FIG. 14, a patterned photoresist 80 is formed on the second surface S2 of the substrate 10. The patterned photoresist 80 includes multiple openings O10, through each of which portions of the substrate 10 are exposed. In some embodiments, the opening O10 is over and substantially aligned with the second photodiode region 30.

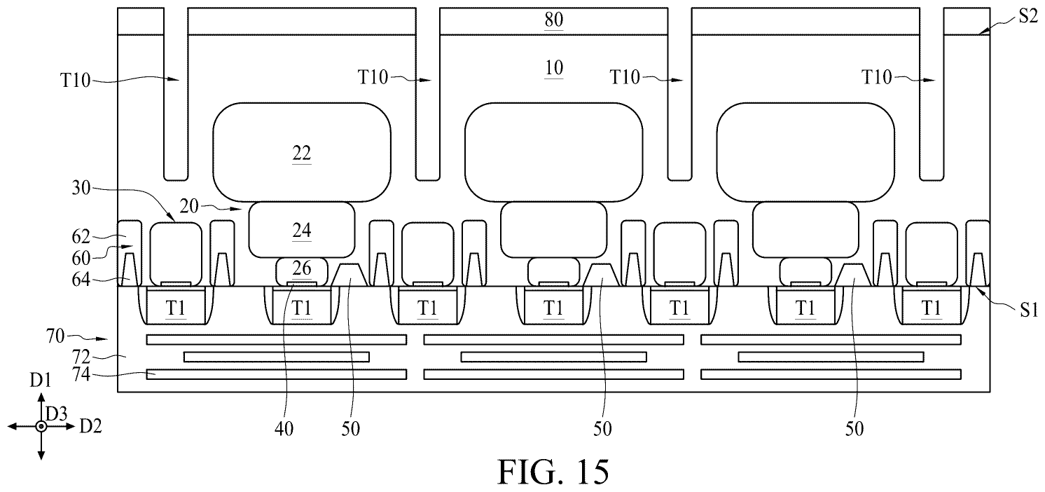

Referring to FIG. 15, an etching operation is performed to remove portions of the substrate 10. In some embodiments, the etching operation is a metal-assisted chemical etching (MACE) operation. The MACE operation may be a wet chemical etching of silicon (Si) or silicon oxide using metal particles such as gold (Au), platinum (Pt), palladium (Pd), silver (Ag), iron (Fe), nickel (Ni), copper (Cu), aluminum (Al), or the like. The metal particles may be disposed at specific positions of an etch target (for example, silicon of the substrate 10) and guided to predetermined directions by, for example, a magnetic force or a gravitational force. An acid such as hydrofluoric acid (HCl) or hydrofluoric acid (HF) and an oxidizing agent such as hydrogen peroxide may be used to react with the metal particles. The oxidizing agent may react with the hydrofluoric acid to generate positive holes (h⁺) on surfaces of the metal particles. The created holes may react with silicon of the substrate 10. The silicon of the substrate 10 may be dissolved according to the following reaction:

$$Si + 6 HF + 4 {h}^{+} \to Si {F}_{6}^{2 -} + 6 {H}^{+}$$

In some embodiments, a first step of the MACE operation vertically etches the silicon of the substrate 10 using the patterned photoresist 80 as an etching mask. Portions of the substrate 10 exposed by the openings O10 are recessed from the second surface S2 toward the first surface S1, and therefore multiple first trenches T10 are formed. In some embodiments, the first trench T10 extends along the first direction D1. In some embodiments, the first trench T10 is substantially between two neighboring isolation structures 60. The used etchant and dissolved silicon forms an etching by-product. A cleaning operation may be used to remove the etching by-product after the first trenches T10 are formed. In some embodiments, the first trench T10 is over and substantially aligned with the second photodiode region 30.

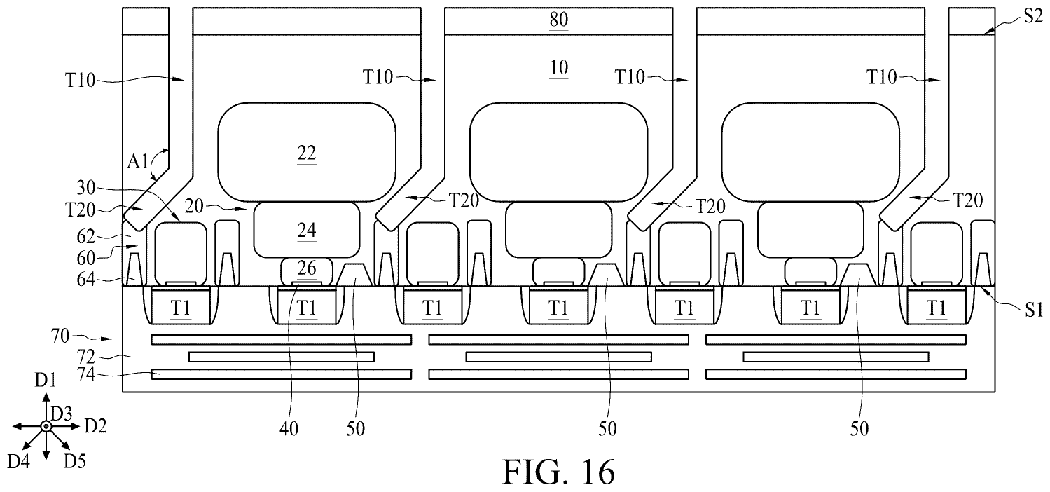

Referring to FIG. 16, in some embodiments, a second step of the MACE operation etches the substrate 10 from the first trench T10 along a fourth direction D4 between the first direction D1 and the second direction D2 to form a second trench T20. In some embodiments, the fourth direction D4 has a first tilt angle A1 with respect to an extending direction of the first trench T10 (i.e., the first direction D1). The first tilt angle A1 between the fourth direction D4 and the first direction is less than 180 degrees. In some embodiments, the change of the direction of the etch is performed by controlling the distributions of the metal particles in the first trench T10 so as to determine the first tilt angle A1. In some embodiments, the first tilt angle A1 between the first trench T10 and the second trench T20 is between 90 degrees and 180 degrees. In some embodiments, a corner is formed at the connecting point between the trench T10 and the trench 20. In some embodiments, the second step dissolves the silicon of the substrate 10 along the fourth direction D4 from the first trench T10. That is, a formation of the second trench T20 starts from a tip of the first trench T10 toward one of the isolation structures 60 next to the second photodiode region 30 directly below the first trench T10. In some embodiments, the second step of the MACE operation partially etches some of the isolation structures 60. The second trench T20 is in communication with the first trench T10 and separated from the second photodiode region 30. After the second trenches T20 are formed, a cleaning operation may be used to remove an etching by-product generated during the second step of the MACE operation.

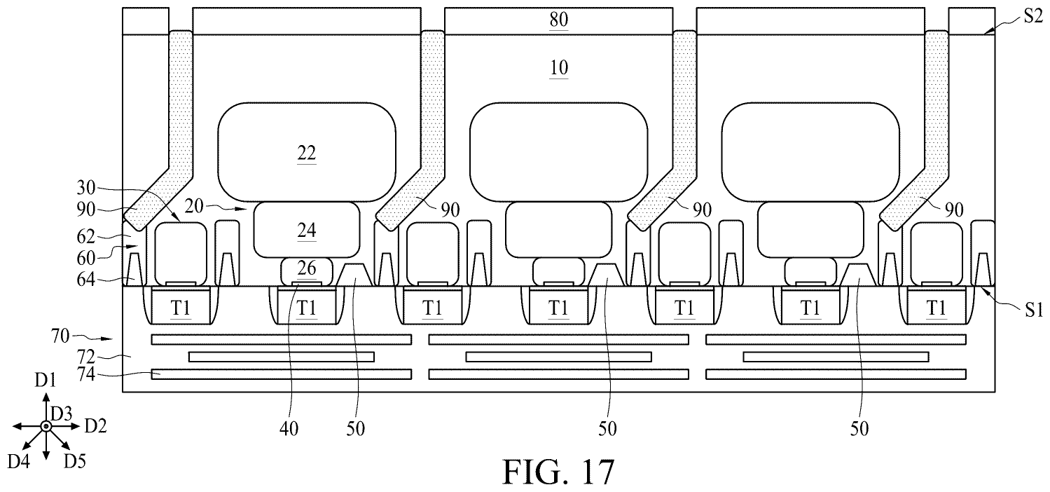

Referring to FIG. 17, a filling material 90 is deposited into the first trench T10 and the second trench T20. In some embodiments, the filling material 90 includes silicon or silicon oxide. A planarization operation is used to remove excess filling material 90 over the second surface S2 of the substrate 10. Subsequently, the patterned photoresist 80 is formed on the second surface S2 again.

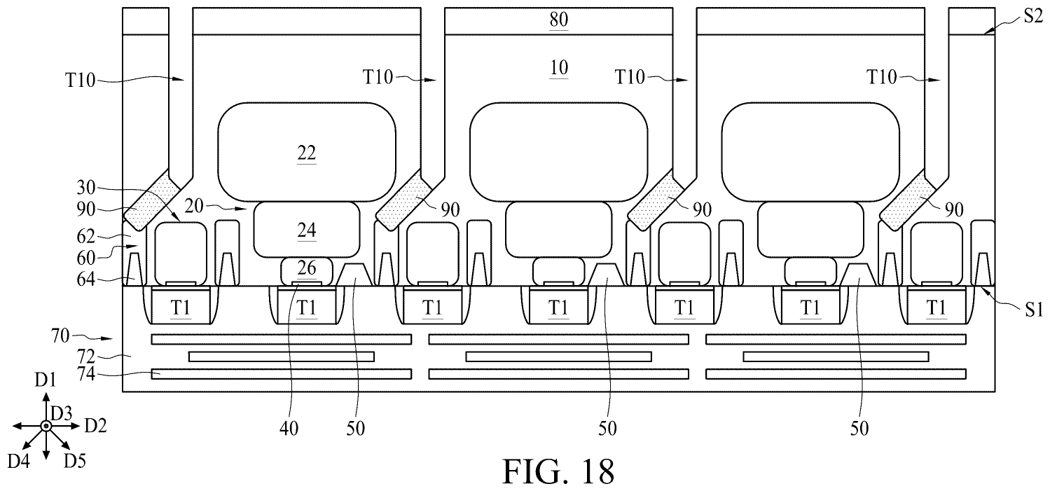

Referring to FIG. 18, in some embodiments, a third step of the MACE operation vertically etches the filling material 90 to reproduce the first trenches T10. Portions of the filling material 90 still remain in the second trenches T20. A cleaning operation may be used to remove an etching by-product generated during the third step of the MACE operation.

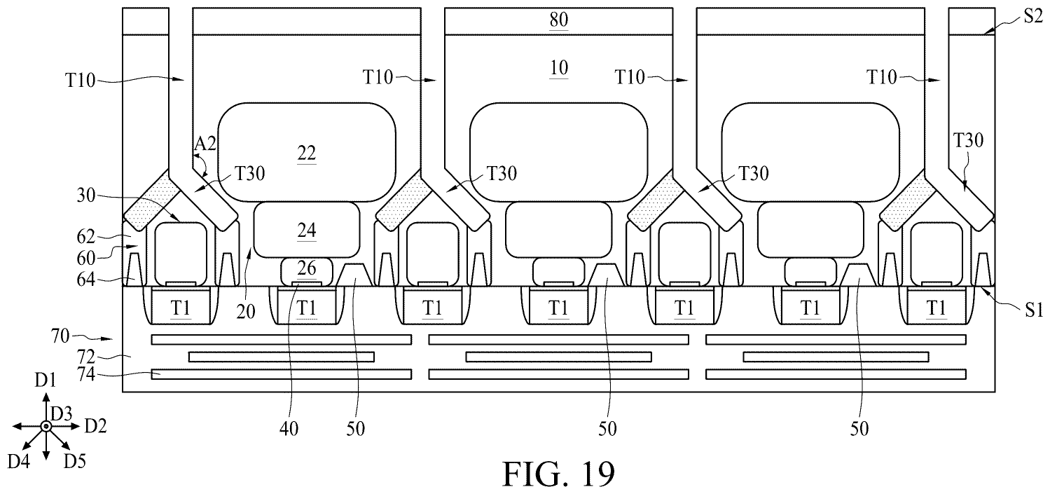

Referring to FIG. 19, in some embodiments, a fourth step of the MACE operation etches the substrate 10 from the first trench T10 along a fifth direction D5 between the first direction D1 and the second direction D2 but opposite to the fourth direction D4 to form a third trench T30. In some embodiments, the fifth direction D5 has a second tilt angle A2, different from the tilt angle A1, with respect to the extending direction of the first trench T10 (i.e., the first direction D1). In some embodiments, a corner is formed at the connecting point between the trench T10 and the trench 20. The second tilt angle A2 between the fifth direction D5 and the first direction is less than 180 degrees. In some embodiments, the second angle A2 between the first trench T10 and the third trench T30 is between 90 degrees and 180 degrees. In some embodiments, the fourth step dissolves the silicon of the substrate 10 along the fifth direction D5 from the first trench T10. That is, a formation of the third trench T30 starts from the tip of the first trench T10 toward the other isolation structure 60 next to the second photodiode region 30 directly below the first trench T10. In some embodiments, the fourth step of the MACE operation partially etches the other isolation structures 60. The third trench T30 is contiguous with the first trench T10 and separated from the second photodiode region 30. After the third trenches T30 are formed, a cleaning operation may be used to remove an etching by-product generated during the fourth step of the MACE operation.

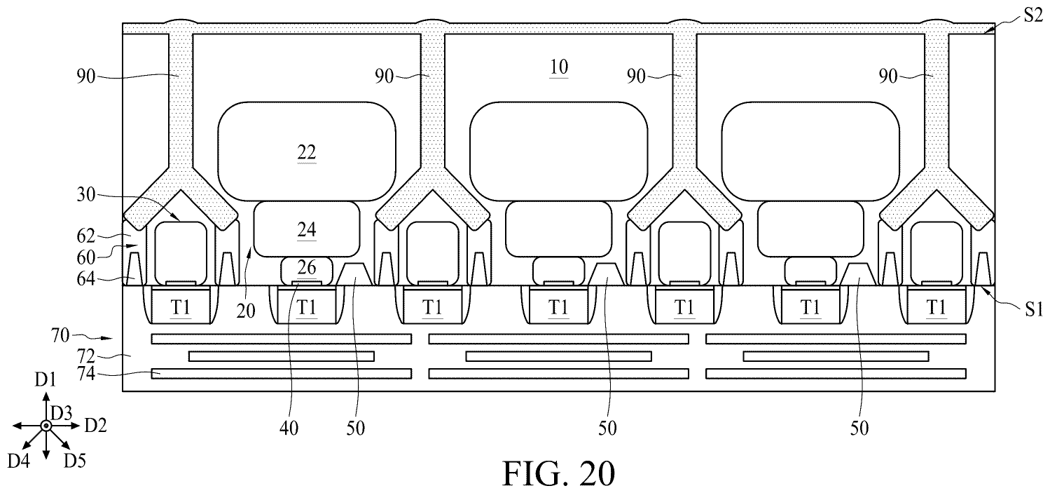

Referring to FIG. 20, in some embodiments, the patterned photoresist 80 is removed, and the filling material 90 is deposited into the first trench T10 and the third trench T30.

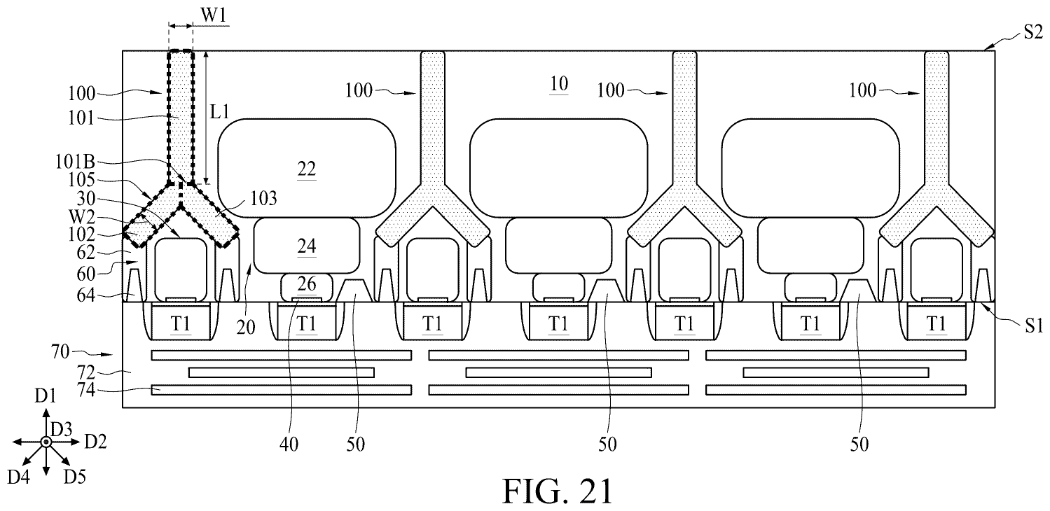

Referring to FIG. 21, a planarization operation is used to remove excess filling material 90 over the second surface S2 of the substrate 10. As a result, the isolation members 100 are formed in the substrate 10. In some embodiments, the isolation member 100 is over and substantially aligned with the second photodiode region 30. In some embodiments, the isolation member 100 includes a first isolation portion 101, a second isolation portion 102 and a third isolation portion 103 connected with each other. The second isolation portion 102 and the third isolation portion 103 may be collectively referred to as branch portions 105. In some embodiments, the first isolation portion 101 has a width W1 between about 200 nanometers (nm) and about 500 nm. In some embodiments, the second isolation portion 102 or the third isolation portion 103 has a width W2 between about 100 nm and about 300 nm. The first to third isolation portions 101 to 103 form an inverted-Y shape in a cross-sectional view. In some embodiments, a length L1 of the first isolation portion 101 along the first direction D1 is adjustable. The first isolation portion 101 can be designed to be long enough such that the second isolation portion 102 and the third isolation portion 103 are close to the second photodiode region 30 but not in contact with the second photodiode region 30. In some embodiments, the isolation members 100 and the first photodiode regions 20 are alternately arranged along the second direction D2.

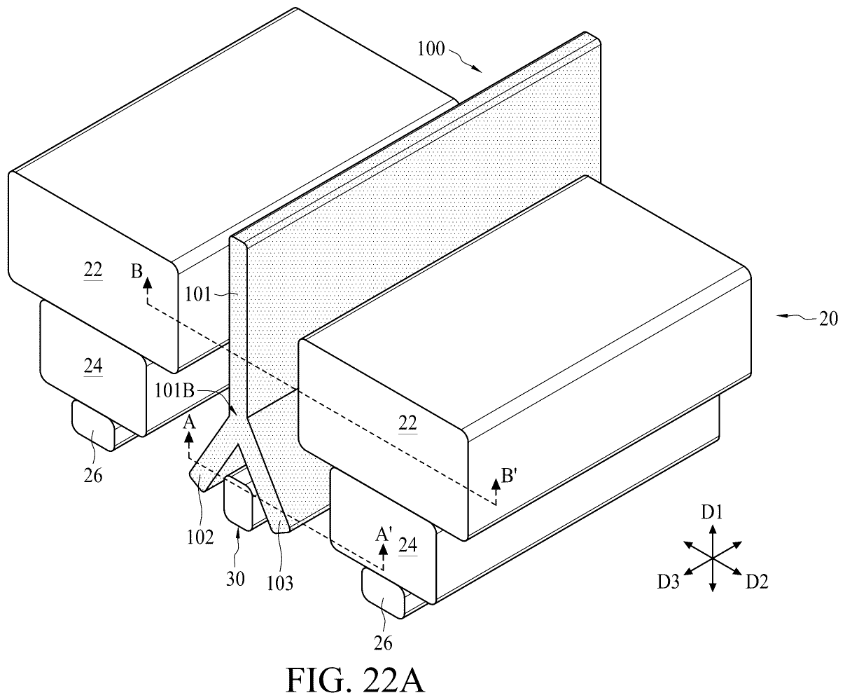

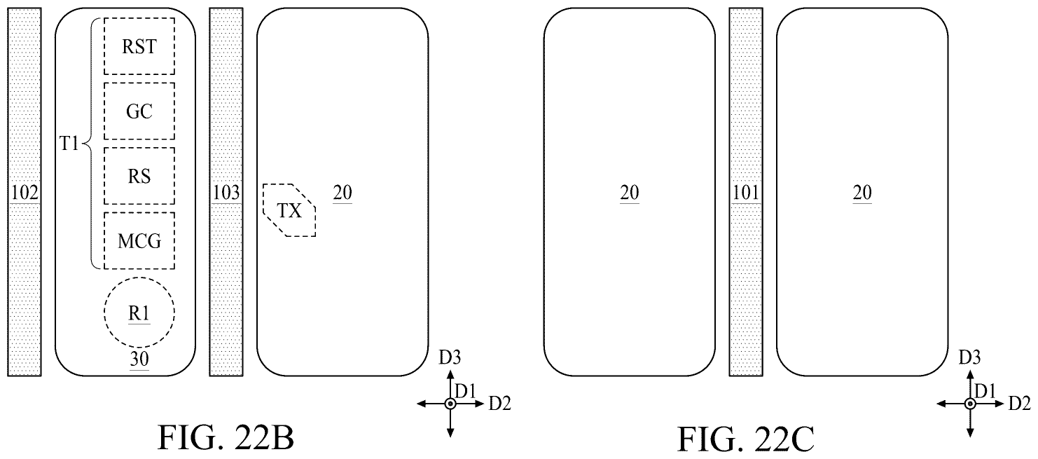

FIG. 22A is a schematic perspective view of the isolation member 100 in FIG. 21. The first to third isolation portions 101 to 103 include strips of walls extending along the third direction D3. Referring to FIG. 21 and FIG. 22, the first isolation portion 101 extends from the second surface S2 toward the first surface S1 of the substrate 10 (i.e., along the first direction D1). The second and third isolation portions 102 and 103 are connected to a bottom portion 101B of the first isolation portion 101.

FIG. 22B is a schematic top view along line AA′ of the isolation member 100 in FIG. 22A. In some embodiments, at a level of line AA′, the second photodiode region 30 is substantially interposed between the second isolation portion 102 and the third isolation portion 103, that is, the branch portions 105 of the isolation member 100. The third isolation portion 103 is substantially between the first photodiode region 20 and the second photodiode region 30.

FIG. 22C is a schematic top view along line BB′ of the isolation member 100 in FIG. 22A. In some embodiments, at a level of line BB′, the first isolation portion 101 is interposed between two neighboring first photodiode regions 20. The line AA′ and the line BB′ in FIG. 22A are different levels of the isolation member 100. The transistors T1 and the protection element R1 not at the level of line AA′ or line BB′ are represented by dashed squares and dashed circles, respectively. Specifically, the transistors T1 and the protection element R1 are below the first photodiode region 20 or the second photodiode region 30.

In some embodiments, the isolation member 100 is connected to two neighboring isolation structures 60 through the second isolation portion 102 and the third isolation portion 103. That is, the second isolation portion 102 is connected to one isolation structure 60, and the third isolation portion 103 is connected to the other isolation structure 60. In some embodiments, the isolation member 100 and the isolation structure 60 separate the first photodiode region 20 from the second photodiode region 30. In other embodiments, the isolation member 100 separates the first photodiode region 20 from the second photodiode region 30. In some embodiments, the isolation member 100 provides for optical cross-talk reduction or elimination where an optical signal is produced from incident radiation that passes between adjacent first photodiode region 20 and second photodiode region 30.

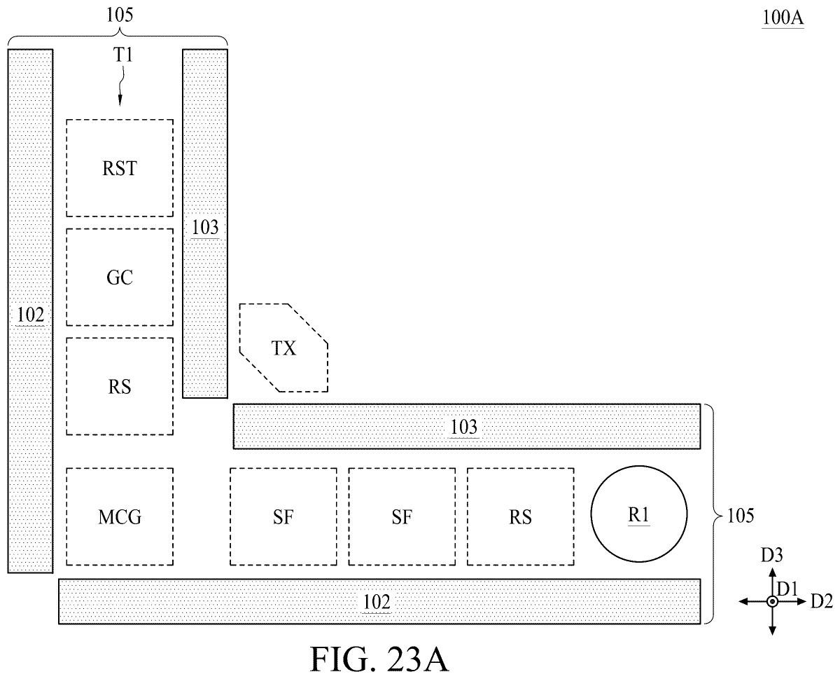

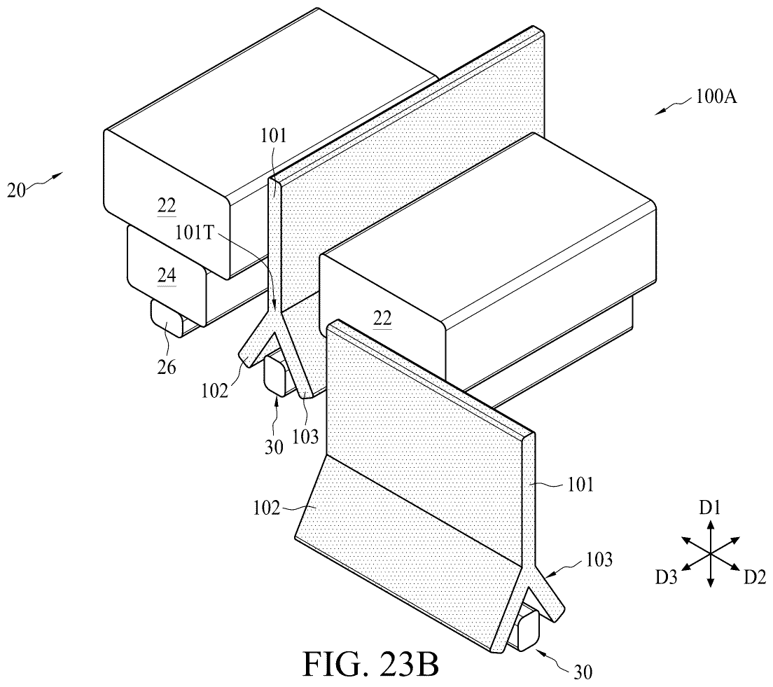

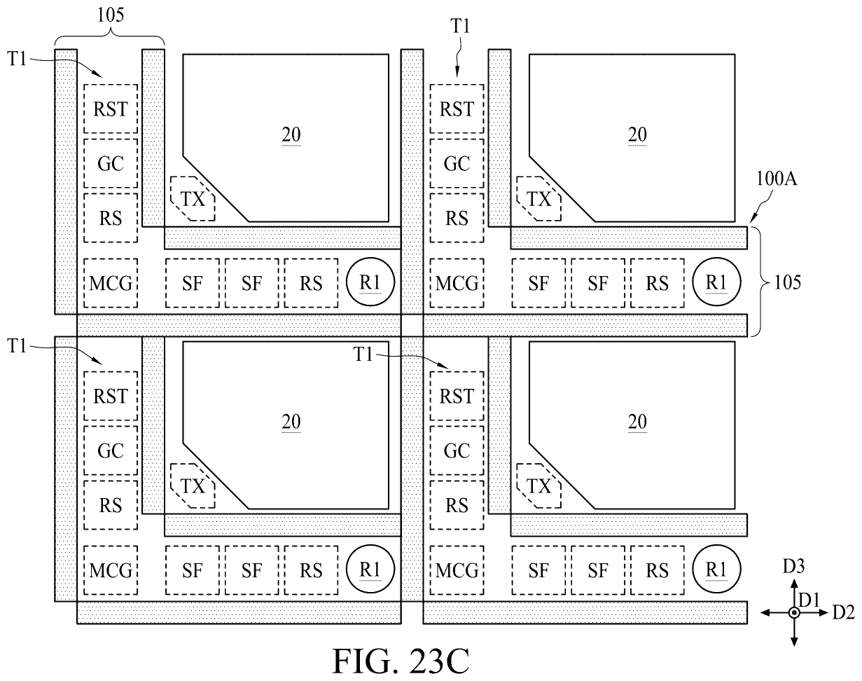

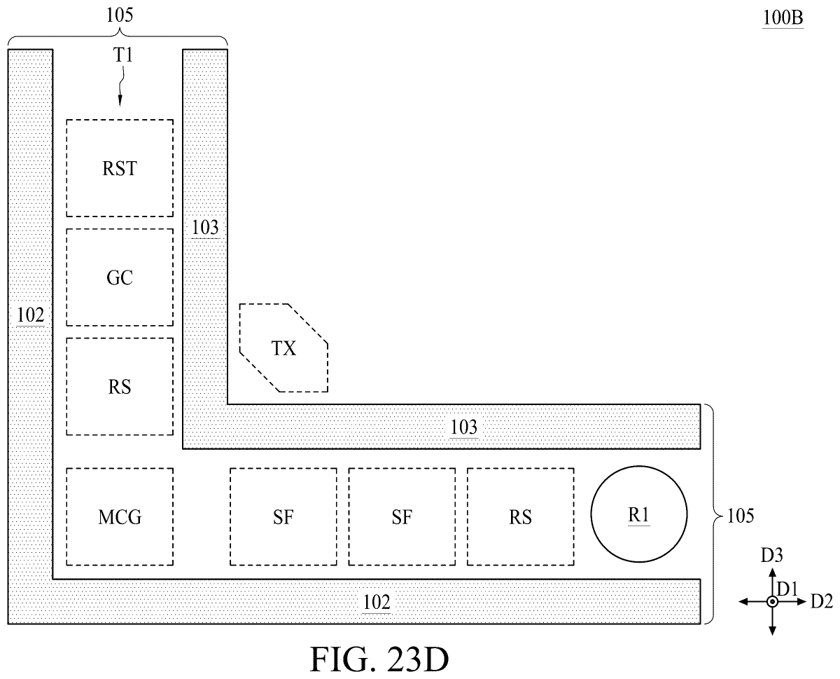

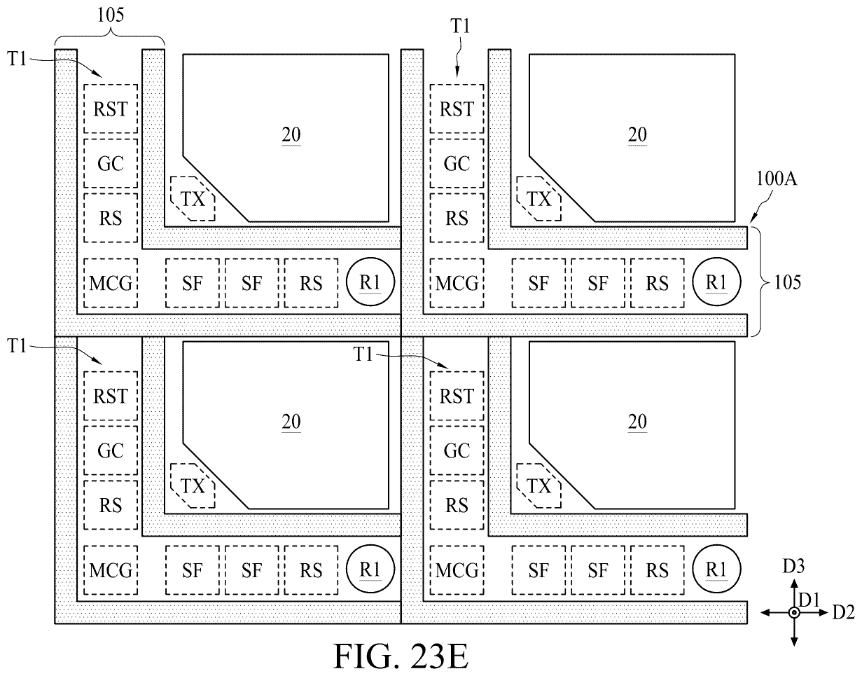

FIGS. 23A and 23B are schematic top and perspective views of an isolation member 100A, according to various embodiments of the present disclosure. In some embodiments, the isolation member 100A includes two branch portions 105. In such embodiments, one of the two branch portions 105 extend along the second direction D2, and the other branch portions 105 extend along the third direction D3. In some embodiments, the two branch portions 105 are not connected to each other. The transistors T1 and the protection element R1 are not at the same level of the two branch portions 105, and are represented by dashed squares and dashed circles, respectively. Specifically, the transistors T1 and the protection element R1 are below the isolation member 100A along the first direction D1.

FIG. 23C is a schematic top view showing multiple arranged isolation members 100A, according to various embodiments of the present disclosure. In some embodiments, multiple first photodiode regions 20 are arranged in an array of 2×2 image sensing cells. Each of the isolation members 100A or the branch portions 105 may be disconnected from the adjacent isolation members 100 or branch portions 105 extending in different directions. Each of the first photodiode regions 20 is surrounded by branch portions 105 of neighboring isolation members 100A. The second photodiode regions 20 are not shown for simplicity, but are substantially positioned over the transistors T1 along the first direction D1.

FIG. 23D is a schematic top view of an isolation member 100B, according to various embodiments of the present disclosure. The isolation member 100B is similar to the isolation member 100A in FIG. 23A, except that two branch portions 105 are connected. In some embodiments, the two branch portions 105 are connected in a manner that the second isolation portion 102 is connected to the second isolation portion 102, and the third isolation portion 103 is connected to the third isolation portion 103.

FIG. 23E is a schematic top view showing multiple arranged isolation members 100B, according to various embodiments of the present disclosure. FIG. 23E is similar to FIG. 23C, except that the isolation members 100B are connected with each other. In some embodiments, the isolation members 100A in FIG. 23C and the isolation members 100B in FIG. 23E provide for optical cross-talk reduction or elimination where an optical signal is produced from incident radiation that passes between adjacent first photodiode regions 20, adjacent second photodiode regions 20 or between adjacent first and second photodiode regions 20 and 30.

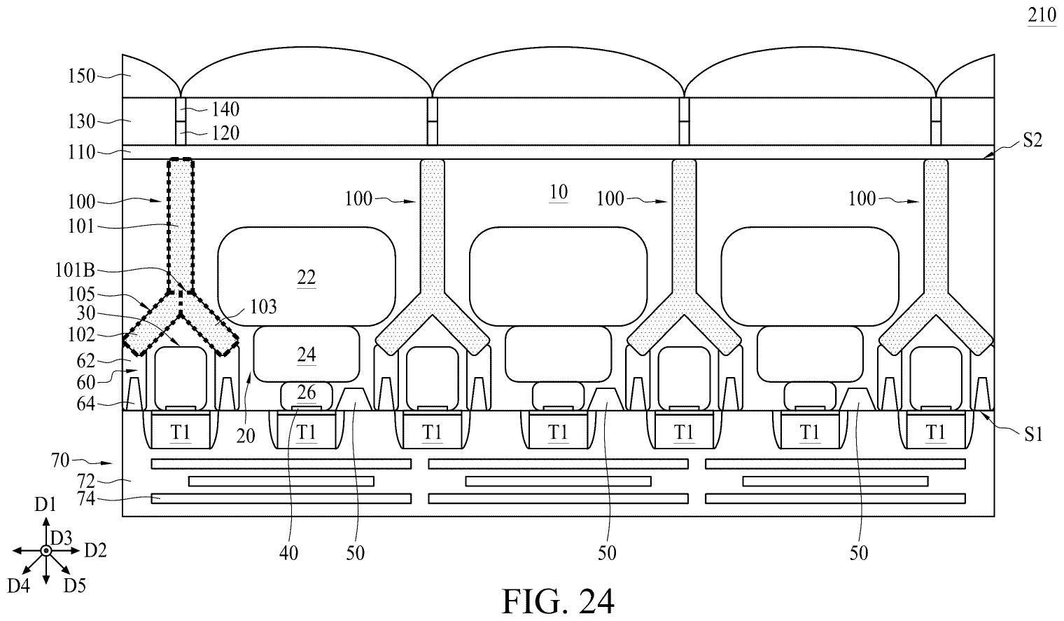

In operation 221 of FIG. 1, multiple optical components are formed on the second surface S2 of the substrate 10, as shown in FIG. 24. In some embodiments, an anti-reflection layer 110 is deposited or coated on the second surface S2. The anti-reflection layer 110 may be formed of oxide, nitride, a high-k dielectric material such as aluminum oxide (AlO), tantalum oxide (TaO), hafnium oxide (HfO), hafnium silicon oxide (HfSiO), hafnium aluminum oxide (HfAlO), hafnium tantalum oxide (HfTaO), or a combination thereof. The anti-reflection layer 110 may minimize light reflection and thus allow more light to reach the first photodiode regions 20 and the second photodiode regions 30.

In some embodiments, multiple metal grids 120 are formed on the anti-reflection layer 110 and respectively aligned with the isolation members 100. The metal grids 120 may be made of a reflective material such as silver (Ag), titanium (Ti), tantalum (Ta), platinum (Pt), tungsten (W), aluminum (Al), copper (Cu), or a combination thereof. The metal grids 120 can be used to reduce optical interference between neighboring photodiode regions. The metal grids 120 are used to reflect refracted or reflected light back to color filters, thereby reducing cross talk.

In some embodiments, multiple color filters 130 are disposed on the anti-reflection layer 110 and are near the metal grids 120. The color filter 130 is aligned with the first photodiode region 20. The color filter 130 is used to allow light or radiation having a wavelength within a specific range to pass. For example, a color filter 130 used to transmit incident light with a wavelength between about 400 nm and about 750 nm. Adjacent color filters 130 are separated by one metal grid 120. When the metal grid 120 and the color filter 130 have different thicknesses, space over the metal grid 120 can be filled with a dielectric layer 140 made of oxide or nitride. The color filters 130 are separated from the substrate 10 by the anti-reflection layer 110.

In other embodiments, the dielectric layer 140 is disposed on the anti-reflection layer 110. In such embodiments, the metal grids 120 are separately embedded in the dielectric layer 140 and are aligned with the isolation members 100. That is, the dielectric layer 140 separates the metal grids 120 from the substrate 10. The color filters 130 are surrounded by the dielectric layer 140, and top surfaces of the color filters 130 are coplanar with or below a top surface of the dielectric layer 140.

In some embodiments, a microlens 150 is formed on the color filter 130 and at least a portion of the dielectric layer 140. In some embodiments, the microlens 150 is made of at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The microlens 150 has a curved surface (or convex surface) that directs an incoming light and facilitates condensation of the incident light. The microlens 150 is aligned with the color filter 130 and the first photodiode region 20. At this stage, the formation of the image sensing structure 210 is complete. The image sensing structure 210 is an image sensing device or a portion of the image sensing device. The image sensing structure 210 is, for example, a backside illumination (BSI) image sensing structure.

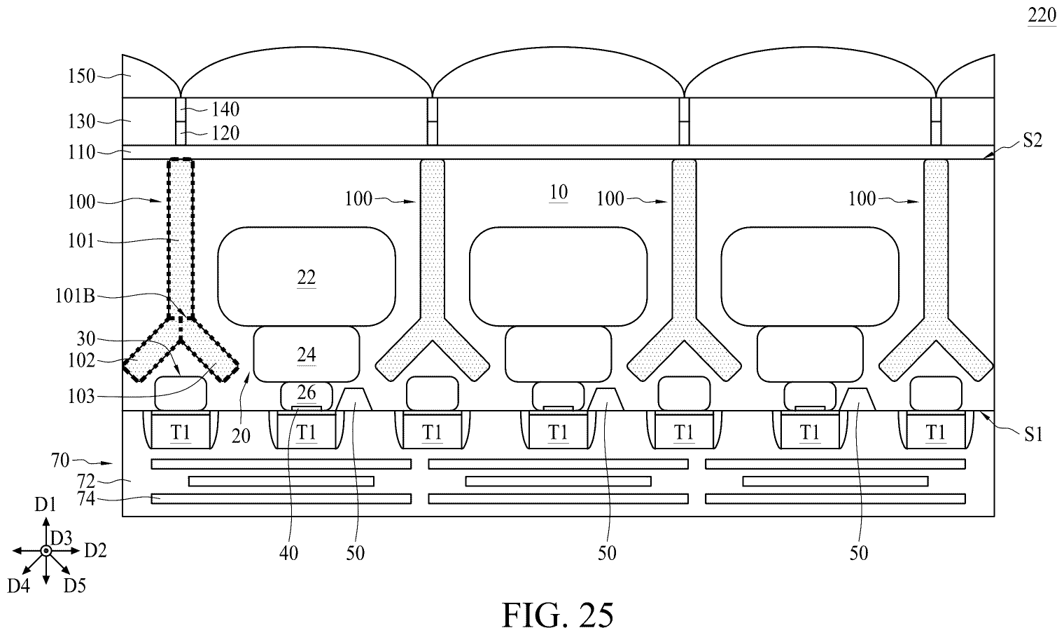

FIGS. 25 to 28 show schematic cross-sectional views of other image sensing structures 220, 230, 240 and 250, according to various embodiments of the present disclosure. The image sensing structures 220, 230, 240 and 250 are similar to the image sensing structure 210 and can be formed using the method 200 with some modifications.

FIG. 25 shows the image sensing structure 220. In some embodiments, the image sensing structure 220 does not include the isolation structures 60. The isolation member 100 is disposed between two adjacent first photodiode regions 20 and over a corresponding second photodiode region 30. The second photodiode region 30 is disposed between branch portions 105 of the isolation member 100, that is, the second isolation portion 102 and the third isolation portion 103. In some embodiments, the isolation member 100 encloses the corresponding second photodiode region 30 and separates the second photodiode region 30 from a neighboring first photodiode region 20.

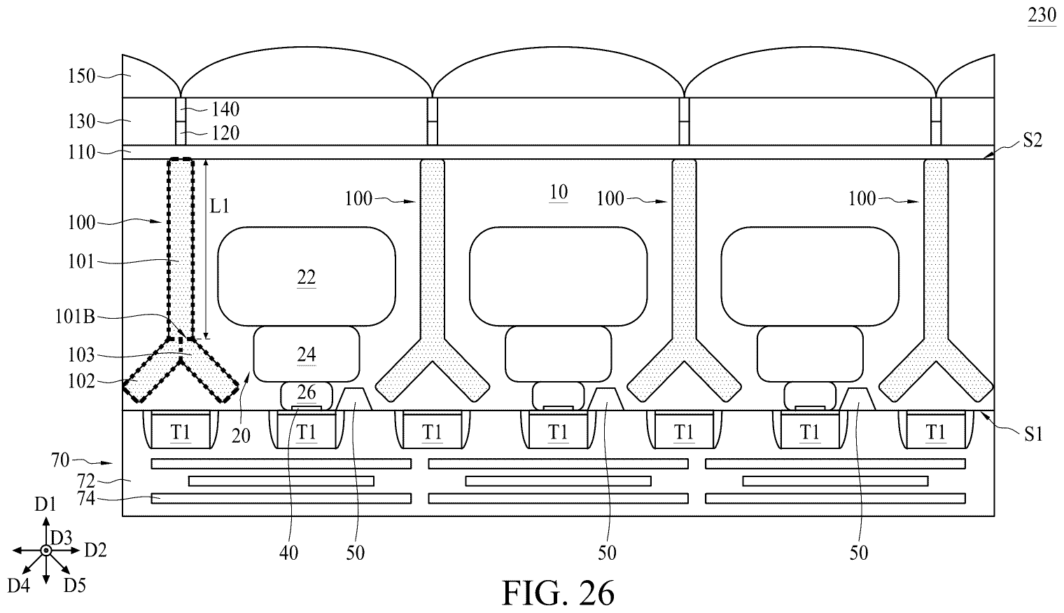

FIG. 26 shows the image sensing structure 230. In some embodiments, the image sensing structure 230 does not include the second photodiode regions 30. In some embodiments, the length L1 of the first isolation portion 101 is determined to be great enough such that the second isolation portion 102 and the third isolation portion 103 are close to the corresponding transistor T1 but still apart from the first surface S1 of the substrate 10. The isolation member 100 separates two adjacent first photodiode regions 20 and reduces optical cross-talk between the two first photodiode regions 20 when an optical signal is generated from incident radiation that passes the first photodiode regions 20.

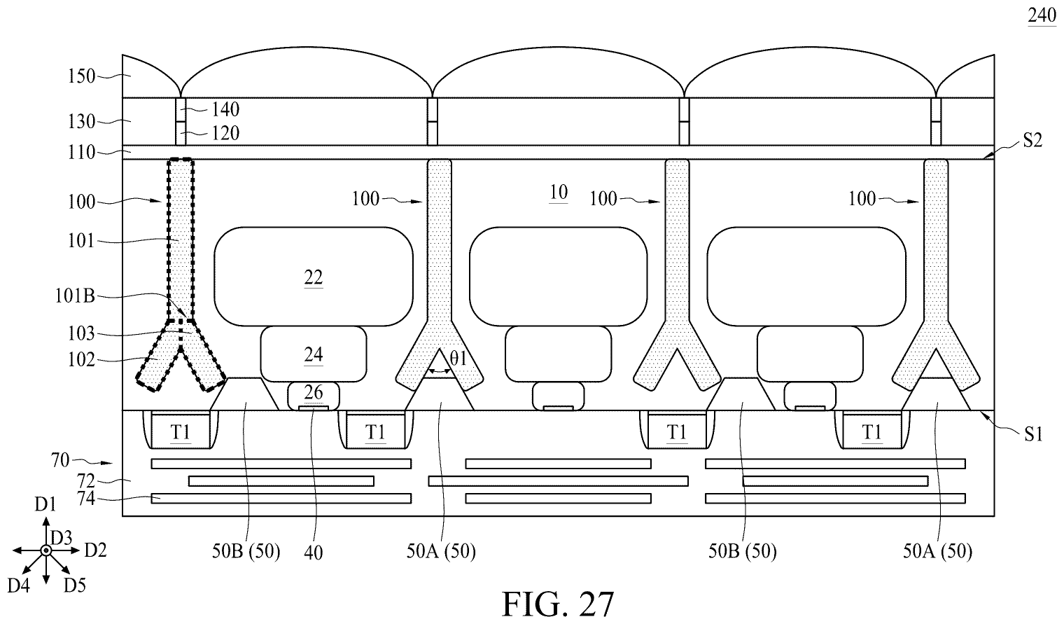

FIG. 27 shows the image sensing structure 240. The image sensing structure 240 is similar to the image sensing structure 230 in FIG. 25, except that the image sensing structure 240 includes a different arrangement of the floating diffusion regions 50. In some embodiments, the floating diffusion regions 50 includes a first floating diffusion region 50A disposed within coverage of the isolation member 100 and a second floating diffusion region 50B outside the coverage of the isolation member 100. In some embodiments, the first floating diffusion region 50A is disposed directly below the isolation member 100. The first floating diffusion region 50A may be disposed below the first isolation portion 101 and between the second isolation portion 102 and the third isolation portion 103. An angle θ1 between the second isolation portion 102 and the third isolation portion 103 is adjustable in the fabrication stage of the isolation member 100. The angle θ1 is less than 180 degrees such that the second isolation portion 102 and the third isolation portion 103 are not parallel to each other. In some embodiments, the isolation member 100 contacts the floating diffusion region 50A. In some other embodiments, the isolation member 100 is proximal to the floating diffusion region 50A but not in contact with the floating diffusion region 50A. In some embodiments, the second floating diffusion region 50B is disposed between the isolation member 100 and the first photodiode region 20.

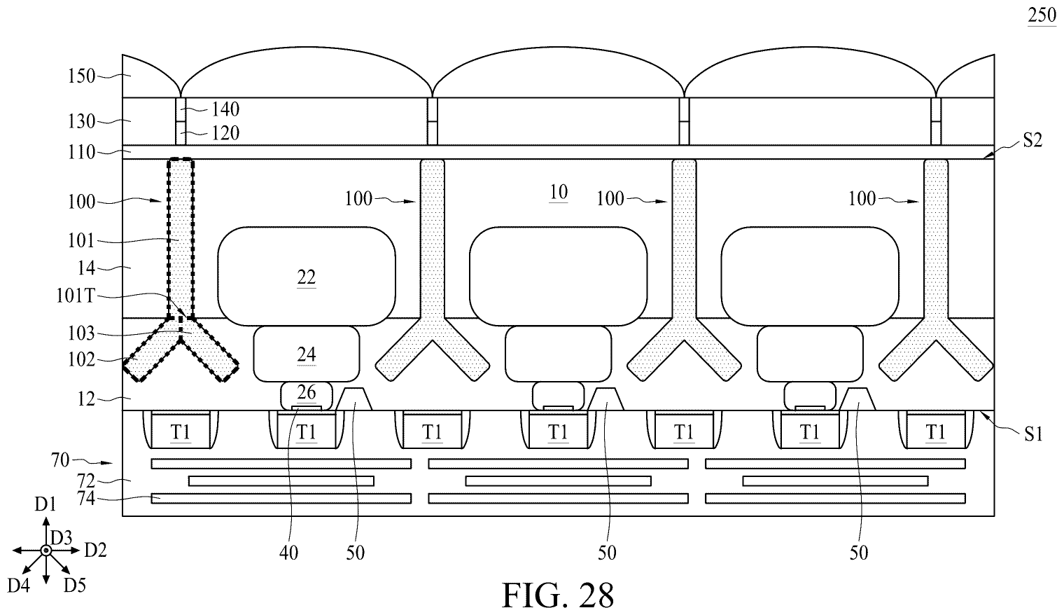

FIG. 28 shows the image sensing structure 250. The image sensing structure 250 is similar to the image sensing structure 230 in FIG. 25, except that the substrate 10 includes a first doped region 12 near the first surface S1 of the substrate 10 and a second doped region 14 near the second surface S2 of the substrate 10. The doped regions 12 and 14 may be formed prior to operation 203. In some embodiments, the doped regions 12 and 14 are formed by separately implanting the substrate 10 with dopants of the first conductivity type. In some embodiments, the doped regions 12 and 14 have different dopant concentrations. In some embodiments, the dopant concentrations of the doped regions 12 and 14 are respectively greater than that of the substrate 10. The doped regions 12 and 14 may be referred to as P-type wells. In some embodiments, an interface of the first doped region 12 and the second doped region 14 is substantially level with the bottom portion 101B of the first isolation portion 101, but the present disclosure is not limited thereto. The interface of the first doped region 12 and the second doped region 14 may be higher or lower than the bottom portion 101B. In some embodiments, the second isolation portion 102 and the third isolation portion 103 are disposed in the first doped region 12, and the first isolation portion 101 is disposed in the first doped region 14, but the present disclosure is not limited thereto.

One aspect of the present disclosure provides a method of forming an image sensing structure. The method includes: providing a substrate having a first surface and a second surface opposite to the first surface; forming a first photodiode region and a second photodiode region in the substrate; and forming an isolation member in the substrate and adjacent to the first photodiode region or the second photodiode region, wherein the formation of the isolation member includes: etching the substrate from the second surface to form a first trench recessed from the second surface toward the first surface; etching the substrate from the first trench along a first direction diagonal to an extending direction of the first trench to form a second trench; filling the first trench and the second trench with silicon; etching the substrate from the second surface to reform the first trench; etching the substrate from the first trench along a second direction diagonal to the extending direction of the first trench to form a third trench, wherein the second direction is opposite to the first direction in a cross-sectional view; and filling the first trench and the third trench with silicon.

One aspect of the present disclosure provides another method of forming an image sensing structure. The method includes: providing a substrate having a first surface and a second surface opposite to the first surface; forming a first photodiode region and a second photodiode region in the substrate; forming a first transistor and a second transistor on the first surface, wherein the first transistor is over the first photodiode region and the second transistor is over the second photodiode region; and etching the substrate from the second surface to form a first trench recessed from the second surface toward the first surface, wherein the first trench is substantially aligned with the first photodiode region; etching the substrate from the first trench to form a second trench recessed from the first trench toward the second transistor; and depositing silicon into the first trench and the second trench.

Another aspect of the present disclosure provides an image sensing structure. The image sensing structure includes: a substrate having a first surface and a second surface opposite to the first surface; a first photodiode and a second photodiode in the substrate; a first transistor and a second transistor on the first surface and respectively over the first photodiode and the second transistor; and an isolation member in the substrate, wherein the isolation member includes: a first portion extending from the second surface toward the first surface; a second portion extending from a bottom portion of the first portion toward the first transistor; and a third portion extending from the bottom portion of the first portion toward the second transistor.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein be utilized according to the present invention. Accordingly, the appended claims are intended to include within their scope such processes, machines, manufacture, compositions of matter, means, methods and steps.

What is claimed is:

1. A method, comprising:
providing a substrate having a first surface and a second surface opposite to the first surface;
forming a first photodiode region and a second photodiode region in the substrate; and
forming an isolation member in the substrate and adjacent to the first photodiode region or the second photodiode region, wherein the formation of the isolation member includes:
etching the substrate from the second surface to form a first trench recessed from the second surface toward the first surface;
etching the substrate from the first trench along a first direction diagonal to an extending direction of the first trench to form a second trench;
filling the first trench and the second trench with silicon oxide;
etching the substrate from the second surface to reproduce the first trench;
etching the substrate from the first trench along a second direction diagonal to the extending direction of the first trench to form a third trench, wherein the second direction is opposite to the first direction in a cross-sectional view; and
filling the first trench and the third trench with silicon oxide.

2. The method of claim 1, wherein the isolation member extends from the second surface toward the first surface and has an inverted-Y shape in the cross-sectional view.

3. The method of claim 1, further comprising:
forming a first isolation structure and a second isolation structure separated from each other and extending from the first surface into the substrate.

4. The method of claim 3, wherein
the first trench is between the first isolation structure and the second isolation,
the formation of the second trench starts from a tip of the first trench toward the first isolation structure,
and the formation of the third trench starts from the tip of the first trench toward the second isolation structure.

5. The method of claim 3, wherein one end of the isolation member is connected to the first isolation structure, and another end of the isolation member is connected to the second isolation structure.

6. The method of claim 1, wherein the etching of the substrate includes using an oxidizing agent and metal particles.

7. The method of claim 1, prior to filling the first trench and the second trench with silicon, further comprising performing a cleaning operation to remove an etching product generated from the substrate.

8. The method of claim 1, when an angle between an extending direction of the second trench and an extending direction of the third trench is less than 180 degrees.

9. The method of claim 1, wherein the second trench and the third trench are separated from the first surface of the substrate.

10. A method, comprising:
providing a substrate having a first surface and a second surface opposite to the first surface;
forming a first photodiode region and a second photodiode region in the substrate;
forming a first transistor and a second transistor on the first surface, wherein the first transistor is over the first photodiode region and the second transistor is over the second photodiode region; and
etching the substrate from the second surface to form a first trench recessed from the second surface toward the first surface, wherein the first trench is substantially aligned with the first photodiode region;
etching the substrate from the first trench to form a second trench recessed from the first trench toward the second transistor; and
depositing silicon oxide into the first trench and the second trench.

11. The method of claim 10, where the isolation member separates the first photodiode region and the second photodiode region.

12. The method of claim 10, wherein the etching of the substrate is a metal-assisted chemical etching.

13. The method of claim 10, wherein the second photodiode region has a size greater than a size of the first photodiode region.

14. The method of claim 10, after the formation of the second trench, further comprising:
removing an etching product generated from the substrate;
depositing silicon oxide into the first trench and the second trench;
reproducing the first trench;
etching the substrate from the first trench to form a third trench recessed from the first trench, wherein the third trench faces away the second transistor; and
depositing silicon oxide into the first trench and the third trench to form an isolation member.

15. The method of claim 14, wherein the second trench and the third trench are over the first photodiode.

16. The method of claim 14, wherein the isolation member is separated from the first surface.

17. A device, comprising:
a substrate having a first surface and a second surface opposite to the first surface;
a first photodiode and a second photodiode in the substrate;
a first transistor and a second transistor on the first surface and respectively over the first photodiode and the second transistor; and
an isolation member in the substrate, wherein the isolation member includes:
a first portion extending from the second surface toward the first surface;
a second portion extending from a bottom portion of the first portion toward the first transistor; and
a third portion extending from the bottom portion of the first portion toward the second transistor.

18. The device of claim 17, further comprising:
a doping well near the first surface and between the first transistor and the second transistor; and
an isolation structure surrounded by the doping well.

19. The device of claim 18, wherein a tip portion of the second portion or a tip portion of the third portion is in contact with the isolation structure.

20. The device of claim 18, further comprising a floating diffusion region extending from the first surface toward the second surface, wherein the floating diffusion region is substantially aligned with the first portion and between the second and third portions.
